(19) United States
(12) Patent Application Publication
(10) Pub. No.: US 2016/0201220 A1
(43) Pub. Date: Jul. 14, 2016

(54) METHODS OF FABRICATING POLYGON-SECTIONAL RODLIKE INGOT AND SUBSTRATE WITH ORIENTATION MARKER OR ROUNDED CORNERS, RODLIKE INGOT AND SUBSTRATE

(71) Applicant: INSTITUTE OF SEMICONDUCTORS, CHINESE ACADEMY OF SCIENCES, Beijing (CN)

(72) Inventors: Jinmin LI, Beijing (CN); Junxi WANG, Beijing (CN); Xiaoyan YI, Beijing (CN); Qingfeng KONG, Beijing (CN); Wenjun WANG, Beijing (CN); Qiang HU, Beijing (CN); Jianchang YAN, Beijing (CN); Tongbo WEI, Beijing (CN); Ping MA, Beijing (CN); Hongxi LU, Beijing (CN); Panfeng JI, Beijing (CN); Jinxia GUO, Beijing (CN)

(21) Appl. No.: 14/895,179

(22) PCT Filed: Dec. 27, 2013
(86) PCT No.: PCT/CN2013/090636

§ 371 Date: Dec. 1, 2015

(30) Foreign Application Priority Data
Sep. 26, 2013 (CN) 201310444715.1

(51) Int. Cl. C30B 25/18; B28D 5/04; C30B 29/16; C30B 29/66; C30B 29/64

(52) U.S. Cl. CPC C30B 25/18; C30B 29/66; C30B 29/64; C30B 29/16; B28D 5/04

(57) ABSTRACT

The present invention discloses a method of forming a polygon-sectional rodlike ingot having an orientation marker or rounded corners, a rodlike ingot and a sheet substrate so formed. The method comprises: selecting one of sides of the polygon-sectional rodlike ingot that is parallel to an axial direction thereof as a first feature of a surface orientation marker; forming a minisize notch, which is parallel to an edge, in the one of sides selected as the first feature in the axial direction of the rodlike ingot, as a second feature of the orientation marker; and processing the rodlike ingot to form rounded corners. The sheet substrate is obtained by cutting the rodlike ingot.

### BACKGROUND

1. Technical Field

The present invention is related to semiconductor technology field, and particularly, to a polygonal sheet substrate used in process of fabricating a LED by metal organic chemical vapor deposition (MOCVD) equipment.

2. Description of the Related Art

The third-generation semiconductor materials represented by GaN and its alloys are new type of semiconductor materials which have obtained great interests in recent more than decade years. This type of semiconductor materials have lots of outstanding properties, such as a wide forbidden band, a high electron saturation drift speed, a small dielectric constant, a good thermal conduction, a stable structure and so on. Thus, nitride materials produce an excellent application prospect in the fields of optoelectronic and microelectronic technologies.

The current method of fabricating GaN-based opto-electronic devices, such as LEDs, mainly relates to MOCVD epitaxial technology. Generally, many common substrates may be used, such as gallium arsenide (GaAs), gallium phosphide (GaP), indium phosphide (InP), silicon (Si), silicon carbide (SiC), sapphire (Al₂O₃), or lithium aluminate (LiAlO₂), etc. The currently used substrate is commonly circular and has a common diameter of 5.08 cm (2 inches), 10.16 cm (4 inches), or 15.24 cm (6 inches), etc. The graphite susceptor is designed in a shape of circle with a diameter in a range from 10 cm to 150 cm for convenience of rotation during epitaxial growth. Placement of the circular substrate on the circular graphite susceptor will cause a reduced effective usage area. Particularly, a surface area of the graphite susceptor would be wasted to more extend for a 6-inches, 8-inches or bigger sized substrates. It is desired to reduce a wasted surface area of the graphite susceptor.

In order to reduce the wasted surface area of the graphite susceptor, the conventional standard circular sheet substrate is designed and improved. A polygonal substrate, such as a quadrate substrate or a hexagonal substrate, is developed to replace the circular sheet substrate in order to increase fill-in ratio of the graphite susceptor and thus reduce the wasted surface area of the graphite susceptor and increase yield of the apparatus in one operation cycle.

In addition, during an epitaxial growth process, there is the strict requirement for a surface orientation of a sheet substrate to be used in order to obtain crystal lattice matching between different materials. Particularly, a front surface and a back surface of the sheet substrate are of different processing characteristics for, such as, grinding, polishing, cleaning and packaging processes. Thus, it is necessary to exactly distinguish the front surface and the back surface of the substrate for each process.

For a polygonal substrate, such as a quadrate substrate, it is a common approach to select two corners and cut the selected corners to obtain two cut sides with different lengths. The two cut sides with different lengths may be used as markers to identify the surface orientation of the substrate. However, when there is no large difference between lengths of the two cut sides, the markers for surface orientation have a low identification ability. In this case, the subsequent procedures would be subject to inconvenience and thus yield and the production efficiency would be decreased.

Thus, it is desired to develop a polygonal substrate with easily and reliably identifiable surface orientation, and a quadrate-sectional or polygon-sectional rodlike ingot, and a method of marking a surface orientation of a sheet substrate.

### SUMMARY OF THE DISCLOSURE

An object of the present invention is to provide a quadrate-sectional or polygon-sectional rodlike ingot and a method of forming a surface orientation marker on the rodlike ingot, which enables high identification ability, and easy and reliable implementation of identification.

Another object of the present invention is to provide a method of forming a polygonal substrate with a surface orientation marker from a rodlike ingot.

A further object of the present invention is to provide a quadrate or polygonal substrate with rounded corners and a method of arranging the substrates in a graphite susceptor, which improves availability of the graphite susceptor, and thus further increases growth efficiency of subsequent epitaxial processes. For example, it will achieve the yield of a chemical vapor deposition apparatus, and reduce cost of an epitaxial chip, meeting requirements of application. Further, the substrate may be favor of protecting SiC coating of the graphite susceptor and thus prolong lifetime of the graphite susceptor.

A still further object of the present invention is to provide a method of forming a polygon-sectional rodlike ingot with rounded corners, which renders an increased yield of subsequent substrates and epitaxial products.

According to an aspect of the present invention, there is provided a method of forming a polygon-sectional rodlike ingot with an orientation marker, the method comprising:

selecting, one of sides of the polygon-sectional rodlike ingot that is parallel to an axial direction axial direction of the rodlike ingot, as a first feature of the orientation marker; and

forming a minisize notch, which is parallel to an edge of the rodlike ingot, in the one of sides with the first feature in the axial direction of the rodlike ingot, as a second feature of the orientation marker.

According to an aspect of the present invention, there is provided a method of forming a polygonal substrate with an orientation marker, the method comprising: forming the rodlike ingot according to the above method; and cutting the rodlike ingot to obtain a sheet-like substrate as required.

According to an aspect of the present invention, there is provided a polygonal substrate with rounded corners, each rounded corner with a radius in a range from 0.1 mm to 10 mm.

According to an aspect of the present invention, there is provided a method of forming a polygon-sectional rodlike ingot with an orientation marker and rounded corners, the method comprising:

step a: selecting, as a first feature of the surface orientation marker, one of sides of the polygon-sectional rodlike ingot that is parallel to an axial direction thereof;

Step b: forming a minisize notch, which is parallel to an edge of the rodlike ingot in the one of sides having the first feature in the axial direction of the rodlike ingot, as a second feature of the surface orientation marker; and

step c: forming rounded corners of the rodlike ingot;

wherein the step c is performed prior to or posterior to the step a and the step b.

According to an aspect of the present invention, there are provided a rodlike ingot and a substrate fabricated according to the above methods.

### BRIEF DESCRIPTION OF THE DRAWINGS

In order to further describe contents of the present invention in detail, description will be made hereinafter in combination with embodiments and accompanying drawings, in which:

FIG. 1 is a flow chart according to an embodiment of the present invention;

FIG. 2 is a schematic structural diagram of a first feature and a second feature formed on a regular hexagon-sectional rodlike ingot according to an embodiment of the present invention;

FIG. 3 is a schematic structural diagram of a first feature and a second feature formed on a quadrate-sectional rodlike ingot according to an embodiment of the present invention;

FIG. 4 is a schematic structural diagram of a regular hexagon-sectional rodlike ingot having rounded corners and an orientation marker according to an embodiment of the present invention;

FIG. 5 is a schematic structural diagram of a quadrate-sectional rodlike ingot having rounded corners and an orientation marker according to an embodiment of the present invention;

FIG. 6 is a schematic structural diagram of a graphite susceptor according to an embodiment of the present invention;

FIG. 7 is a schematic structural diagram of a square substrate having rounded corners according to an embodiment of the present invention; and

FIG. 8 is a schematic structural diagram of another graphite susceptor according to an embodiment of the present invention.

### DETAILED DESCRIPTION OF THE EMBODIMENTS

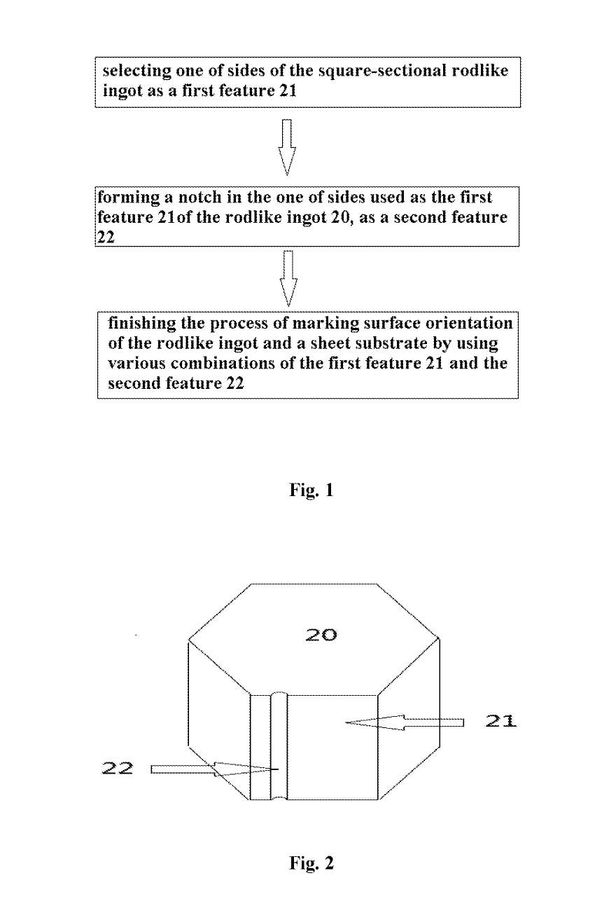

FIGS. 1-3 show quadrate-sectional or polygon-sectional rodlike ingots and a method of forming a surface orientation marker on the quadrate-sectional or polygon-sectional rodlike ingot, according to a first embodiment. The method includes: selecting, one of sides of the polygon-sectional rodlike ingot that is parallel to an axial direction axial direction of the rodlike ingot, as a first feature of the orientation marker; and forming a minisize notch, which is parallel to an edge of the rodlike ingot, in the one of sides as the first feature in the axial direction of the rodlike ingot, as a second feature of the orientation marker.

Specifically, the method comprises:

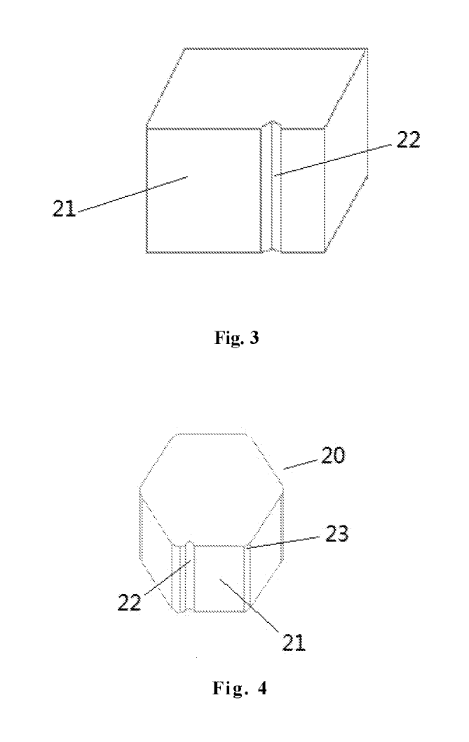

step 1: selecting a random cylinder surface of the polygon-sectional rodlike ingot 20 that is parallel to an axial direction thereof as a first feature 21 for the surface orientation marker, wherein the polygon-sectional rodlike ingot 20 may be made of sapphire, silicon carbide, gallium nitride, aluminum nitride, gallium oxide, zinc oxide or monocrystalline silicon. According to an embodiment of the invention, the polygon-sectional rodlike ingot 20 has a polygonal cross section. Alternatively or additionally, the polygon-sectional rodlike ingot 20 may have a cross section of square or rectangle, as shown in FIG. 3. Alternatively or additionally, the polygon-sectional rodlike ingot 20 may have a hexagonal cross section, as shown in FIG. 2. Alternatively or additionally, the polygon-sectional rodlike ingot 20 may have a cross section of other type of polygon, such as pentagon, octagon, or the like. The one of sides, which is selected as the first feature 21 and is parallel to the axial direction of the rodlike ingot, may be any of cylinder surfaces of the rodlike ingot 20.

Step 2: forming a notch in the one of sides as the first feature 21 in the axial direction of the rodlike ingot 20, as a second feature 22 of the surface orientation marker. The formed notch may be parallel to a side of the rodlike ingot 20. The notch may be formed in a suitable size depending on a diameter of the rodlike ingot. Generally, the notch is fabricated as a minisize notch in order to minimize influence on the subsequent usage of the substrate. The rodlike ingot may be cut to obtain a polygonal sheet substrate. The notch, as the second feature 22, may be located at a random position on the one of sides as the first feature 21, except at the central bisection line of the one of sides. According to an embodiment of the present invention, the minisize notch, as the second feature 22, has a V-shaped cross section. Alternatively or additionally, the minisize notch, as the second feature 22, has a semicircular cross section. The minisize notch, as the second feature 22, may be formed to have a cross section of other recognizable shapes as desired.

Step 3: finishing the process of identifying surface orientations of the rodlike ingot and the sheet substrate by combining various shapes of the first feature 21 and the second feature 22 to mark the surface orientation of the polygonal sheet substrate.

In this embodiment, as shown in FIG. 2, a semi-circular notch is provided as the second feature 22 to form the orientation marker for the hexagon-sectional gallium oxide rodlike ingot and the sheet substrate and is used to identify the surface orientation of the sheet substrate.

Firstly, a hexagon-sectional gallium oxide rodlike ingot 20 that is passed inspection is selected and a head end transverse plane and a tail end transverse plane of the rodlike ingot are formed.

The rodlike ingot is then placed erectly on a stable workpiece platform with the head thereof upward. A random cylinder surface of the rodlike ingot is selected as a first feature 21. The selected cylinder surface is brought to face the operator and a straight line, which is parallel to the side of the rodlike ingot, is marked by a marker pen at a position on the selected cylinder surface near a left side edge of the rodlike ingot. By this way, the straight line marks the position for forming the notch 22, as the second feature.

The marked gallium oxide rodlike ingot 20 is placed on a grinder workpiece platform and is provided with a semicircle-shaped notch at the marked position by using a semicircle type grinding tool, finishing formation of the second feature 22. The first feature 21 and the second feature 22 form the complete surface orientation marker of the rodlike ingot.

The rodlike ingot with the first feature 21 and the second feature 22 is cut to obtain a sheet substrate. By this way, the obtained sheet substrate also has the first feature 21 and the second feature 22 and thus its surface orientation can be clearly identified.

A gallium oxide rodlike ingot that is produced according to the above method from an ingot is placed on a workpiece platform and is rotated such that the one of sides 21 with the notch faces the operator. The gallium oxide rodlike ingot is then turned such that the notch 22 is located at left hand side of the operator. By this way, the top surface of the gallium oxide rodlike ingot is necessarily used as the head thereof.

The gallium oxide rodlike ingot is then cut, obtaining a plurality of sheet substrates. A substrate is fabricated according to standard operation process.

According to an embodiment of the present invention, a rodlike ingot is processed to produce sheet substrates to be used. A random sheet substrate is placed on a workpiece platform and is rotated such that a side 21 including a notch faces toward the operator. The sheet substrate is turned such that the notch 22 is located at left hand side with relative to the operator. By this way, the top surface of the sheet substrate is necessarily used as a front surface thereof. According to an embodiment of the present invention, front and rear surfaces of the substrate may be easily determined by the marker on the substrate.

According to the first embodiment of the present invention, there is also provided a method of fabricating a polygonal substrate having an orientation marker, the method comprising: fabricating a rodlike ingot according to the above method; and forming a sheet-like substrate by cutting the rodlike ingot.

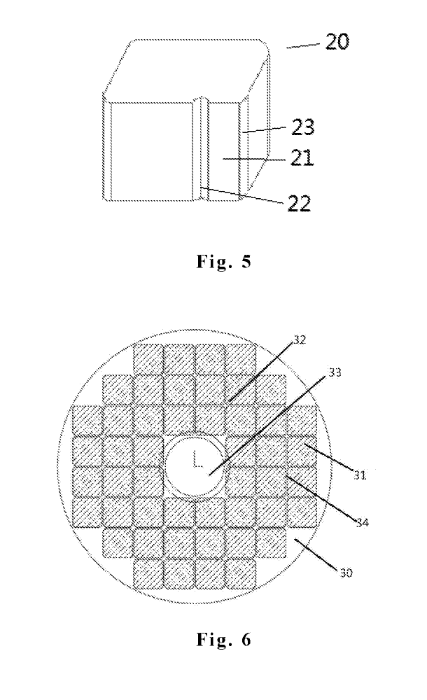

According to a second embodiment of the present invention, a polygonal rodlike ingot 20 may be rounded at edges thereof, as shown in FIGS. 4 and 5, in order to increase yields of subsequent products such as a substrate, an epitaxial wafer and the like. The procedure is shown as below.

Firstly, edges of the polygonal rodlike ingot 20 are rounded, for example, may be ground by a surface-grinding machine or a shaping wheel to obtain an arc surface having a preset curvature radius or a plane with a preset width.

Subsequently, similar to the process of forming an orientation marker according to the first embodiment, one of sides 21 is selected as a first feature and a second feature 22 is formed on the one of sides 21. A combination of the first feature and the second feature form a marker for the polygonal rodlike ingot 20 and a subsequently formed substrate.

In an example, the polygonal rodlike ingot 20 may be made of sapphire, silicon carbide, gallium nitride, aluminum nitride, gallium oxide, zinc oxide or monocrystalline silicon. According to an embodiment of the present invention, the polygonal rodlike ingot 20 may have a polygonal cross section. The polygon-sectional rodlike ingot 20 may have a cross section of square or rectangle, as shown in FIG. 5. The polygon-sectional rodlike ingot 20 may have a hexagonal cross section, as shown in FIG. 4. The polygon-sectional rodlike ingot 20 may have a cross section of pentagon or octagon, etc.

According to the second embodiment of the present invention, there is also provided a substrate fabricated by processing the above polygon-sectional rodlike ingot having rounded chamfers, and there is further provided an epitaxial wafer that has the above substrate as a support base for epitaxial growth.

A third embodiment of the present invention will be described hereinafter with reference to FIGS. 6-8. The existing chemical vapor deposition apparatus has a relative low yield and thus an epitaxial wafer is produced in relative high cost, which does not meet requirements of application. It is investigated and found by the inventor that, in a chemical vapor deposition apparatus in prior art, a substrate arranged in a graphite susceptor is designed in a circular shape, which renders a low availability ratio of the graphite susceptor and then a limited amount of substrates processed in one furnace of the chemical vapor deposition apparatus. As an example, a most common graphite susceptor that is used in K465i type MOCVD available from Veeco company and has a diameter of 45 cm may be filled by 45 circular substrates of 2 inches if no substrate is placed within the central region of the susceptor, only obtaining a surface availability ratio of 53.9% of the graphite susceptor; and, it may be filled by 54 substrates of 2 inches if the central region is also filled with substrates, so that the surface availability ratio of the graphite susceptor is increased up to 64.7%. The availability ratio of the graphite susceptor means that a percentage of a sum of areas of total substrates placed on the graphite susceptor with respect to an area of a circle corresponding to the diameter of the graphite susceptor.

According to an embodiment of the present invention, a surface of the graphite susceptor may be used to the utmost by providing, for example, quadrate substrates thereon. As the availability ratio of the graphite susceptor is increased, yield of the chemical vapor deposition apparatus may be increased and cost of an epitaxial chip may be decreased, meeting requirements of application. Further, circularly rounded corners are favor of the protection of the graphite susceptor so that the SiC coating of the graphite susceptor is prevented from being damaged by four corners of the quadrate substrate.

The schemes of the present invention will be described in detailed with reference to specific embodiments. In order to illuminate the schemes of the present invention in a better way, a structure of a graphite susceptor according to a third embodiment of the present invention will be described in combination with FIG. 6, which only shows a front view of the graphite susceptor 30 for convenience. Optionally, according to an embodiment of the present invention, the substrate for MOCVD epitaxial growth may be made of gallium arsenide (GaAs), gallium phosphide (GaP), indium phosphide (InP), silicon (Si), silicon carbide (SiC), Sapphire (Al₂O₃), or lithium aluminate (LiAlO₂).

According to an embodiment of the present invention, the graphite susceptor 30 has a diameter of 45 cm, which is consistent with that used in the current K465i type machine. The substrate 31 to be placed on the surface of the graphite susceptor is designed to be a square sapphire substrate with four sides of 5 cm in length, which is similar to a diameter of 2-inch circular substrate, but an area thereof is 25% bigger than that of the 2-inch circular substrate. The quadrate substrate has four circularly rounded corners 32 that each have a radius of 2 mm. A central region 33 of the graphite susceptor where no substrate is placed has a side of 10 mm, which is similar to the central region of the susceptor for receiving 45 2-inch substrates used in the K465i type machine. A spacing 34 between these substrates has a width of 2 mm. According to this embodiment of the present invention, 48 square substrates with a side length of 5 cm may be placed on the surface of the graphite susceptor, that is, the availability ratio of the graphite susceptor is 70.1%. Thus, the availability ratio of the graphite susceptor according to this embodiment is increased by 30% with respect to the graphite susceptor in prior art, which receives 45 2-inch substrates while leaving the central region thereof being not occupied and has an availability ratio of 53.9%.

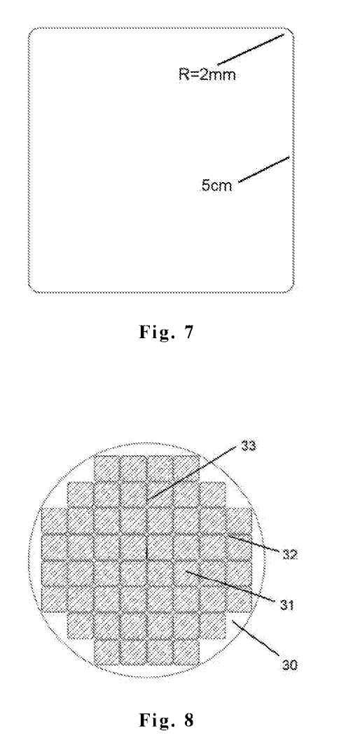

According to an embodiment of the present invention, as shown in FIG. 7, the graphite susceptor 30 is designed to have a diameter of 45 cm, which is consistent with that of the graphite susceptor used in the current improved K465i type machine. A square sapphire substrate is selected as the substrate 31 to be placed on a surface of the graphite susceptor and has a side length of 5 cm, which is similar to the diameter of 2-inch circular substrate, but an area thereof is 25% bigger than that of the 2-inch circular substrate. The quadrate substrate has four corners 32 with rounded chamfers that each has a radius of 2 mm. A central region of the graphite susceptor are fully placed by substrates, which is similar to the graphite susceptor used in the improved K465i type machine in prior art, which receives 54 2-inch substrates on whole surface thereof, including the central region. A spacing 33 between these substrates has a width of 2 mm. According to this embodiment of the present invention, 52 square substrates with a side length of 5 cm may be placed on the surface of the graphite susceptor, that is, the availability ratio of the graphite susceptor is 76.3%. In this instance, the availability ratio of the graphite susceptor according to this embodiment is increased by 18% with respect to the graphite susceptor in prior art, which receives 54 2-inch substrates and has an availability ratio of 64.7% when the central region thereof is also provided thereon with substrates.

According to the third embodiment of the present invention, there is also provided a polygonal substrate with rounded corners, the rounded corners with a radius in a range from 0.1 mm to 10 mm.

In this embodiment, square substrates are used. Optionally, the substrate to be placed may be a quadrate substrate. In other embodiments, the substrate may be other types of polygonal substrate. For example, the substrate may be a regular hexagonal substrate, a regular pentagonal substrate, a regular octagonal substrate, a parallelogram substrate or a rhombic substrate.

The substrate comprises four corners with rounded chamfers with a radius of 2 mm. Depending on requirements for the substrate, the rounded chamfers may have a radius selected a range from 1 mm to 10 mm. According to an embodiment of the present invention, the above polygonal substrate, such as the regular pentagonal substrate, the regular octagonal substrate, the regular hexagonal substrate, may have rounded chamfers with a radius less than 20 mm. The polygonal substrates, such as the regular pentagonal substrate, the regular octagonal substrate, the regular hexagonal substrate, may have rounded chamfers with a radius less than 10 mm, or less than 8 mm, or less than 6 mm, or less than 5 mm, or less than 4 mm, or less than 3 mm, or less than 2.5 mm, or less than 2 mm, or less than 1.8 mm, or less than 1.6 mm, or less than 1.5 mm, or less than 1.4 mm, or less than 1.3 mm, or less than 1.2 mm, or less than 1.1 mm, or less than 1 mm. According to embodiments of the present invention, the polygonal substrate, such as the regular pentagonal substrate, the regular octagonal substrate, the regular hexagonal substrate, may have rounded chamfers with a radius not less than 0.1 mm. According to embodiments of the present invention, the polygonal substrate, such as the regular pentagonal substrate, the regular octagonal substrate, the regular hexagonal substrate, may have rounded chamfers with a radius not less than 0.2 mm, or not less than 0.3 mm, or not less than 0.4 mm, or not less than 0.5 mm, or not less than 0.6 mm, or not less than 0.7 mm, or not less than 0.8 mm, or not less than 0.9 mm, or not less than 1 mm, or not less than 1.2 mm, or not less than 1.4 mm, or not less than 1.6 mm, or not less than 1.8 mm, or not less than 2 mm, or not less than 2.5 mm, or not less than 3 mm, or not less than 3 mm, or not less than 4 mm, or not less than 5 mm.

Optionally, the quadrate substrate has an area in a range from 15 cm² to 2500 cm².

Accordingly, an embodiment of the present invention provides a graphite susceptor that may receive quadrate substrates thereon during a chemical vapor deposition process. The graphite susceptor is provided with quadrate grooves for receiving the substrates. The grooves each have a shape similar to that of the quadrate substrate.

Optionally, a spacing between the quadrate grooves of the graphite susceptor may be in a range from 1 mm to 5 mm.

Optionally, the diameter of the graphite susceptor may be in a range from 10 cm to 150 cm.

The embodiments of the present invention provide the following advantages with respect to the prior arts:

The quadrate substrate according to the embodiments of the present invention may render usage of the surface of the graphite susceptor to the utmost, that is, render increased availability ratio of the graphite susceptor and thus increased yield of a chemical vapor deposition apparatus and reduced cost of an epitaxial chip, meeting requirements of application. Further, the rounded corners are provided to protect the surface of the graphite susceptor, avoiding the SiC coating of the graphite susceptor from be damaged by the four corners of the quadrate substrate.

According to a fourth embodiment of the present invention, different from the third embodiment, there is provided a square-sectional rodlike ingot and a method of marking a surface orientation of a sheet substrate.

Similarly to the above first embodiment, steps 1-3 are performed.

Step 1: selecting one of sides of the square-sectional rodlike ingot that is parallel to an axial direction thereof as a first feature 21 of a surface orientation marker, wherein the square-sectional rodlike ingot 20 may be made of sapphire, silicon carbide, gallium nitride, aluminum nitride, gallium oxide, zinc oxide or monocrystalline silicon. According to an embodiment of the invention, the square-sectional rodlike ingot 20 has a square cross section. The one of sides that is parallel to the axial direction of the rodlike ingot and is used as the first feature 21 may be any of the sides of the rodlike ingot.

Step 2: forming a notch in the one of sides used as the first feature 21 in the axial direction of the rodlike ingot 20, as a second feature 22 of the surface orientation marker. The formed notch may be parallel to a side of the rodlike ingot 20. The notch may be formed in a suitable size according to diameter of the rodlike ingot. Generally, the notch is fabricated as a minisize notch in order to minimize adverse influence on the subsequent usage of the substrate. The rodlike ingot may be cut to obtain a square sheet substrate. The notch, as the second feature 22, may be located at a random position on the one of sides used as the first feature 21, except at positions on the central bisection line of cylinder surface. According to an embodiment of the present invention, the minisize notch, as the second feature 22, has a V-shaped cross section. Alternatively or additionally, the minisize notch, as the second feature 22, has a semicircular cross section. The minisize notch, as the second feature 22, may be formed to have a cross section of other recognizable shapes.

Step 3: finishing the process of marking surface orientation of the rodlike ingot and a sheet substrate by using various combinations of the first feature 21 and the second feature 22 to form surface orientation markers for the rodlike ingot and the sheet substrate.

In an embodiment, for example, a semi-circular notch is provided as the second feature 22 to form the orientation marker for the square-sectional rodlike ingot and the sheet substrate so as to identify the surface orientation of the sheet substrate.

Firstly, a square-sectional rodlike ingot 20which is passed inspection is selected, and is processed to obtain a head transverse end plane and a tail transverse end plane thereof.

The rodlike ingot is then placed erectly, with the head upward, on a stable workpiece platform. One of sides of the rodlike ingot is selected as a first feature 21. The selected cylinder surface is brought to face the operator and a straight line, which is parallel to a side of the one of sides, is marked by a marker pen at a position near a left side of the rodlike ingot. By this way, the straight line marks the position for forming the notch 22, as the second feature.

The marked gallium oxide rodlike ingot is placed on a grinder workpiece platform and is processed to form a semicircular notch at the marked position by using a semicircle type grinding tool, finishing formation of the second feature 22. The first feature 21 and the second feature 22 form the complete surface orientation marker of the rodlike ingot.

The rodlike ingot with the first feature 21 and the second feature 22 is cut to obtain a sheet substrate. By this way, the obtained sheet substrate also has the first feature 21 and the second feature 22 and thus its surface orientation may be clearly identified.

A rodlike ingot that is produced according to the above method from a randomly selected ingot is placed at a workpiece platform and is rotated such that the one of sides 21 with the notch faces the operator. The rodlike ingot is turned such that the notch 22 is located at left hand side of the operator. By this way, the top surface of the gallium oxide rodlike ingot is necessarily the head thereof.

The rodlike ingot is cut, obtaining a plurality of sheet substrates. The substrate is fabricated according to a standard operation process.

According to an embodiment of the present invention, the rodlike ingot is processed to produce sheet substrates to be used. A sheet substrate is placed on a workpiece platform and is rotated such that a side 21 with the notch faces toward the operator. The sheet substrate is turned such that the notch 22 is located at left hand side relative to the operator. By this way, the top surface of the sheet substrate is necessarily a front surface thereof.

The square sheet substrate is further processed to obtain rounded corners. The four corners of the square sheet substrate are formed into rounded corners, each rounded corner with a radius of 2 mm. Optionally, prior to forming the notch on the rodlike ingot, the rodlike ingot is processed to form rounded chamfers. The rodlike ingot with the rounded chamfers is processed by subsequent steps, for example, is processed to form the notch, is cut, and the like. It is known that the order of the step of forming the notch and the step of forming rounded corners may be optional.

The square substrate according to the fourth embodiment of the present invention not only has a side with the notch for marking, through which the front surface of the substrate can be identified by the operator, but also has four rounded corners, each of which is formed to have a radius of, for example, 2 mm. With the square substrate placed on a graphite susceptor, an availability ratio of the graphite susceptor is increased.

In an embodiment of the present invention, the rounded chamfers of the square substrate with the notch each have a radius less than 10 mm, or less than 8 mm, or less than 6 mm, or less than 5 mm, or less than 4 mm, or less than 3 mm, or less than 2.5 mm, or less than 2 mm, or less than 1.8 mm, or less than 1.6 mm, or less than 1.5 mm, or less than 1.4 mm, or less than 1.2 mm, or less than 1.1 mm, or less than 1 mm. In an embodiment of the present invention, the rounded corners of the square substrate with the notch each have a radius not less than 0.1 mm, or not less than 0.2 mm, or not less than 0.3 mm, or not less than 0.4 mm, or not less than 0.5 mm, or not less than 0.6 mm, or not less than 0.7 mm, or not less than 0.8 mm, or not less than 0.9 mm, or not less than 1 mm, or not less than 1.2 mm, or not less than 1.4 mm, or not less than 1.6 mm, or not less than 1.8 mm, or not less than 2 mm, or not less than 2.5 mm, or not less than 3.5 mm, or not less than 4 mm, or not less than 5 mm.

In an embodiment of the present invention, the rodlike ingot may be provided with a notch for marking while being processed to obtain rounded corners. The process and method for forming the notch and corners are similar to those in the above embodiments and may be obtained based on the embodiments of the present invention. In this instance, the rodlike ingot according to embodiments of the present invention may be cut to obtain a plurality of sheet substrates, each sheet substrate having a notch as a surface marker and rounded corners. According to embodiments of the present invention, the rodlike ingot may have a cross section of square, pentagon, hexagon, octagon or any other polygons.

According to a fifth embodiment of the present invention, there is provided a hexagon-sectional rodlike ingot, with a notch and rounded chamfers. According to the fifth embodiment, there is also provided a regular hexagonal substrate, having a notch on a side thereof. When the side with the notch is turned to face towards an operator, the sheet substrate is turned such that the notch is located on the left hand side of the operator, thereby the top surface of the sheet substrate being necessarily the front surface thereof. Further, according to an embodiment, the hexagonal substrate comprises four corners with rounded chamfers each with a radius in a range from 0.1 mm to 10 mm, preferably, with a radius of 2 mm. When the hexagonal substrates according to embodiments are placed on a graphite susceptor, the substrates on the graphite susceptor form a pattern of honeycomb, thereby increasing availability ratio of the graphite susceptor.

A sixth embodiment of the present invention is substantially similar to the fourth embodiment, except that a rodlike ingot having an orientation marker is firstly fabricated, then the rodlike ingot is cut to obtain sheet substrates and subsequently the substrate is processed to form corners with rounded chamfers. In other words, a rodlike ingot and sheet substrates having a minisize notch are firstly fabricated according to the first embodiment, and the substrate is then processed to obtain four rounded corners. The rodlike ingot may have a polygonal cross section, such as square, regular pentagon, regular hexagon, regular octagon or the like. The notch may be a V-shape notch, or may be a semicircular notch, or a notch with other shape.

According to another embodiment of the invention, a quadrate-sectional or other polygon-section rodlike ingot may be firstly processed to obtain rounded corners, and then is cut to produce substrates with rounded corners. The substrate is then processed to form an orientation marker thereon. The processing steps are similar to the above embodiments and may be obtained by those skilled in the art based on the above description.

The others variants of the embodiments of the present invention may be obtained by combining the above embodiments based on the above disclosure. The above embodiments are described to illustrate the purpose, scheme and advantage effect of the present invention. It is understood that the above description is provided for describing the embodiments of the present invention, but limiting the invention in no way. Any modification, replacement or improvement of the above embodiments within the spirit and principle of the present invention may be obtained and fallen within the scope of the invention.

1. A method of forming a polygon-sectional rodlike ingot having an orientation marker, the method comprising:
selecting one of sides of the polygon-sectional rodlike ingot that is parallel to an axial direction thereof as a first feature of a surface orientation marker;
forming a minisize notch, which is parallel to an edge of the rodlike ingot, in the one of sides having the first feature in the axial direction of the rodlike ingot, as a second feature of the surface orientation marker.

2. The method according to claim 1, wherein the polygon-sectional rodlike ingot is made of sapphire, silicon carbide, gallium nitride, aluminum nitride, gallium oxide, zinc oxide or monocrystalline silicon.

3. The method according to claim 1, wherein the polygon-sectional rodlike ingot has a cross section of quadrate, regular pentagon, regular hexagon or regular octagon.

4. The method according to claim 1, wherein the one of sides that is selected as the first feature and parallel to the axial direction of the rodlike ingot is any of cylinder surfaces of the rodlike ingot.

5. The method according to claim 1, wherein the minisize notch, as the second feature, is formed at a random position on the one of sides that is the first feature, except at a central line that halves the one of sides that is the first feature.

6. The method according to claim 5, wherein the minisize notch has a V-shape or semi-circular cross section.

7. A polygon-sectional rodlike ingot having an orientation marker formed according to the method of claim 1.

8. A method of forming a polygonal substrate having an orientation marker, the method comprising:
forming a rodlike ingot according to the method of claim 1;
cutting the rodlike ingot to obtain a sheet-like substrate.

9. A polygonal substrate having an orientation marker fabricated according to the method of claim 8.

10. The polygonal substrate according to claim 9, wherein the polygonal substrate has rounded corners, the circularly rounded corners each having a radius in a range from 0.1 mm to 10 mm.

11. The polygonal substrate according to claim 10, wherein the polygonal substrate is in a form of one of square, rectangle, regular pentagonal, regular hexagonal and regular octagonal.

12. The polygonal substrate according to claim 10, wherein one side of the polygonal substrate has a notch that is not located on a central line halving the side.

13. The polygonal substrate according to claim 12, wherein the notch is a V-shaped or semicircle-shaped notch.

14. A method of forming a polygon-sectional rodlike ingot having an orientation marker and rounded corners, the method comprising:
a) selecting one of sides of the polygon-sectional rodlike ingot that is parallel to an axial direction thereof as a first feature of a surface orientation marker;
b) forming a minisize notch, which is parallel to an edge of the rodlike ingot in the one of sides selected as the first feature in the axial direction of the rodlike ingot, as a second feature of the orientation marker; and
c) processing the rodlike ingot to form rounded corners,
wherein the step c) is performed prior to or posterior to the step a) and the step b).

15. A polygon-sectional rodlike ingot having an orientation marker and rounded corners.

16. A method of forming a polygonal substrate having an orientation marker and rounded corners, the method comprising:
forming a rodlike ingot according to the method of claim 14; and
cutting the rodlike ingot.

17. A method of forming a polygonal substrate having an orientation marker and rounded corners, comprising:
forming a polygonal substrate having an orientation marker and rounded corners according to the method of claim 8; and
processing the polygonal substrate so as to obtain four rounded corners.
